(19) United States
(12) Patent Application Publication
(10) Pub. No.: US 2026/0059761 A1
(43) Pub. Date: Feb. 26, 2026

(54) SEMICONDUCTOR DEVICE

(71) Applicant: Samsung Electronics Co., Ltd., Suwon-si (KR)

(72) Inventors: Jihye Lee, Suwon-si (KR); Youngrok Kwon, Suwon-si (KR); Sunggil Kim, Suwon-si (KR); Yihwan Kim, Suwon-si (KR); Jumi Bak, Suwon-si (KR); Sanguk An, Suwon-si (KR); Sanghyeok Yu, Suwon-si (KR); Kyunghee Yun, Suwon-si (KR); Seongkeun Cho, Suwon-si (KR)

(21) Appl. No.: 19/173,184

(22) Filed: Apr. 8, 2025

(30) Foreign Application Priority Data
Aug. 23, 2024 (KR) 10-2024-0113738

(51) Int. Cl. H10B 43/40; G11C 16/04; H01L 23/00; H01L 25/18; H10B 41/10; H10B 41/27; H10B 41/35; H10B 41/41; H10B 43/10; H10B 43/27; H10B 43/35; H10B 80/00; H10D 80/30

(52) U.S. Cl. CPC H10B 43/40; G11C 16/0483; H01L 24/08; H01L 25/18; H10B 41/10; H10B 41/27; H10B 41/35; H10B 41/41; H10B 43/10; H10B 43/27; H10B 43/35; H10B 80/00; H10D 80/30; H01L 24/32; H01L 24/48; H01L 2224/08145; H01L 2224/32145; H01L 2224/32225; H01L 2224/48147; H01L 2224/48227; H01L 2225/06506; H01L 2225/0651; H01L 2225/06524; H01L 2924/1438

(57) ABSTRACT

A semiconductor device includes a cell structure including gate electrodes and mold insulating layers alternately stacked one by one in a vertical direction, a channel structure extending in the vertical direction through the gate electrodes and the insulating layers, wherein a first end portion of the channel structure protrudes upward from an uppermost mold insulating layer, and a common source layer connected to the first end portion of the channel structure and located on the uppermost mold insulating layer. The uppermost mold insulating layer includes a first low-refractive-index layer on a lower surface of the common source layer, a high-refractive-index layer on a lower surface of the first low-refractive-index layer, and a second low-refractive-index layer on a lower surface of the high-refractive-index layer.

### CROSS-REFERENCE TO RELATED APPLICATION

This application is based on and claims priority under 35 U.S.C. § 119 to Korean Patent Application No. 10-2024-0113738, filed on Aug. 23, 2024, in the Korean Intellectual Property Office, the disclosure of which is incorporated by reference herein in its entirety.

### BACKGROUND

The inventive concept relates to a semiconductor device, and more particularly, to a semiconductor device including a cell structure.

Electronic systems requiring data storage require semiconductor devices capable of storing high volumes of data. To satisfy the excellent performance and low prices demanded by consumers while increasing data storage capacity, there is a demand to increase the integration of semiconductor devices. Because the integration of a two-dimensional or flat semiconductor device is mainly determined based on an area occupied by a unit memory cell, the integration is significantly influenced by the level of a fine pattern forming technique. Although the integration of two-dimensional semiconductor devices has advanced, it remains constrained due to the need for extremely costly equipment to achieve fine patterning. As a result, three-dimensional semiconductor devices, which feature memory cells arranged in a three-dimensional configuration, have been proposed as an alternative.

### SUMMARY

The inventive concept provides a semiconductor device with improved electrical characteristics and reliability.

However, the problems to be solved by the inventive concept are not limited to the problem mentioned above, and other problems that are not mentioned could be clearly understood by those of ordinary skill in the art from the description below.

According to an aspect of the present disclosure, a semiconductor device includes a cell structure including a cell region, a connection region, and a peripheral circuit connection region. The cell structure includes a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes, a channel structure disposed in the cell region and extending in the vertical direction through the plurality of gate electrodes and the plurality of mold insulating layers, wherein a first end portion of the channel structure protrudes upward from the uppermost mold insulating layer, and a common source layer arranged in the cell region, connected to the first end portion of the channel structure, and located on the uppermost mold insulating layer. The uppermost mold insulating layer comprises a first low-refractive-index layer on a lower surface of the common source layer, a high-refractive-index layer on a lower surface of the first low-refractive-index layer, and a second low-refractive-index layer on a lower surface of the high-refractive-index layer.

According to an aspect of the present disclosure, a semiconductor device includes a cell structure including a cell region, a connection region, and a peripheral circuit connection region. The cell structure includes a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes, a channel structure disposed in the cell region and extending in the vertical direction through the plurality of gate electrodes and the plurality of mold insulating layers, wherein a first end portion of the channel structure protrudes upward from the uppermost mold insulating layer, and a common source layer arranged in the cell region, connected to the first end portion of the channel structure, and located on the uppermost mold insulating layer. A refractive index of the common source layer is greater than a refractive index of the uppermost mold insulating layer. The refractive index of the uppermost mold insulating layer is less than a refractive index of the uppermost gate electrode. A thickness, in the vertical direction, of the uppermost mold insulating layer is greater than a thickness, in the vertical direction, of each of the remaining mold insulating layers among the plurality of mold insulating layers.

According to an aspect of the present disclosure, a semiconductor device includes a peripheral circuit structure including a peripheral circuit transistor and a peripheral circuit wiring structure, and a cell structure stacked on the peripheral circuit structure and including a cell region, a connection region, and a peripheral circuit connection region. The cell structure includes a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes, a channel structure disposed in the cell region and extending in the vertical direction through the plurality of gate electrodes and the plurality of mold insulating layers, wherein a first end portion of the channel structure protrudes upward from the uppermost mold insulating layer, a common source layer arranged in the cell region, connected to the first end portion of the channel structure, and located on the uppermost mold insulating layer, a plurality of pad portions respectively extending from the plurality of gate electrodes in the vertical direction and disposed in the connection region, and a stack insulating layer disposed in the connection region and the peripheral circuit connection region and surrounding the plurality of gate electrodes and the plurality of mold insulating layers. A thickness, in the vertical direction, of the uppermost mold insulating layer is greater than a thickness, in the vertical direction, of each of the remaining mold insulating layers among the plurality of mold insulating layers.

### BRIEF DESCRIPTION OF THE DRAWINGS

Embodiments of the inventive concept will be more clearly understood from the following detailed description taken in conjunction with the accompanying drawings in which:

FIG. 1 is a block diagram of a semiconductor device according to embodiments;

FIG. 2 is a circuit diagram illustrating a memory block according to embodiments;

FIG. 3 is a perspective view illustrating a representative structure of a semiconductor device 100 according to embodiments.

FIG. 4 is a plan layout diagram of the semiconductor device of FIG. 3;

FIG. 5 is an enlarged layout diagram of a portion A of the semiconductor device of FIG. 4;

FIG. 6 is a cross-sectional view illustrating the semiconductor device of FIG. 5, taken along lines B1-B1′ and B2-B2′ of FIG. 5;

FIG. 7 is an enlarged view illustrating a portion EX1 of the semiconductor device of FIG. 6;

FIG. 8 is an enlarged view illustrating a portion of a semiconductor device according to embodiments;

FIG. 9 is an enlarged view illustrating a portion of a semiconductor device according to embodiments;

FIG. 10 is an enlarged view illustrating a portion of a semiconductor device according to embodiments;

FIGS. 11A to 11E are cross-sectional views taken along lines B1-B1′ and B2-B2′ of FIG. 5 to illustrate a method of manufacturing a semiconductor device according to embodiments;

FIG. 12 is a block diagram illustrating a data storage system including a semiconductor device according to embodiments;

FIG. 13 is a perspective view illustrating a data storage system including a semiconductor device according to embodiments; and

FIG. 14 is a cross-sectional view illustrating a semiconductor package according to embodiments, taken along line II-II′ of FIG. 13.

### DETAILED DESCRIPTION OF THE EMBODIMENTS

The embodiments may allow various kinds of change or modification and various changes in form, and specific embodiments will be illustrated in drawings and described in detail in the specification. However, it is not intended to limit the embodiments to a particular disclosure form.

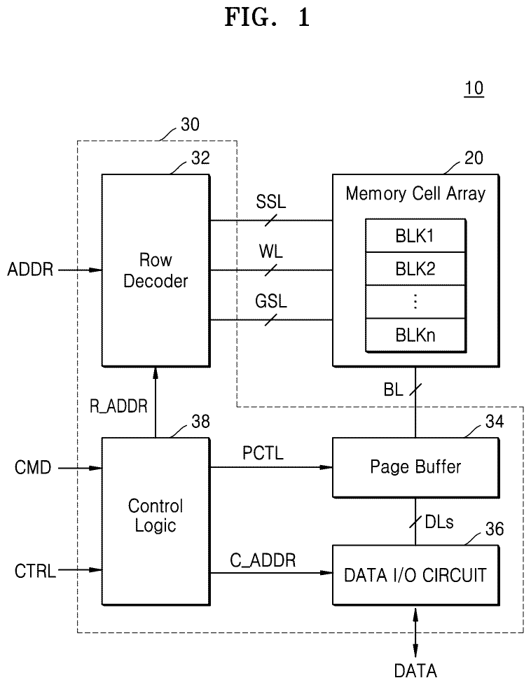

FIG. 1 is a block diagram of a semiconductor device 10 according to embodiments.

Referring to FIG. 1, the semiconductor device 10 may include a memory cell array 20 and a peripheral circuit 30. The memory cell array 20 includes a plurality of memory cell blocks BLK1, BLK2, . . . , and BLKn. Each of the plurality of memory cell blocks BLK1, BLK2, . . . , and BLKn may include a plurality of memory cells. The plurality of memory cell blocks BLK1, BLK2, . . . , and BLKn may be connected to the peripheral circuit 30 through bit lines BL, word lines WL, string select lines SSL, and ground select lines GSL.

The peripheral circuit 30 may include a row decoder 32, a page buffer 34, a data input-output circuit 36, and a control logic 38. Although not shown in FIG. 1, the peripheral circuit 30 may further include an input-output interface, a column logic, a voltage generator, a pre-decoder, a temperature sensor, a command decoder, an address decoder, or an amplification circuit. The memory cell array 20 may be connected to the page buffer 34 through the bit lines BL and connected to the row decoder 32 through the word lines WL, the string select lines SSL, and the ground select lines GSL. In the memory cell array 20, each of a plurality of memory cells included in each of the plurality of memory cell blocks BLK1, BLK2, . . . , and BLKn may be a flash memory cell. The memory cell array 20 may include a three-dimensional memory cell array. The three-dimensional memory cell array may include a plurality of NAND strings, and each of the plurality of NAND strings may include a plurality of memory cells vertically stacked on a substrate and connected to a plurality of word lines WL.

The peripheral circuit 30 may receive an address ADDR, a command CMD, and a control signal CTRL from the outside of the semiconductor device 10 and transmit and receive data DATA to and from a device outside the semiconductor device 10.

The row decoder 32 may select at least one of the plurality of memory cell blocks BLK1, BLK2, . . . , and BLKn in response to the address ADDR from the outside and may select a word line WL, a string select line SSL, and a ground select line GSL of the selected memory cell block. The row decoder 32 may provide, to the word line WL of the selected memory cell block, a voltage for performing a memory operation.

The page buffer 34 may be connected to the memory cell array 20 through the bit lines BL. The page buffer 34 may operate as a write driver during a program operation to apply, to the bit lines BL, a voltage according to the data DATA to be stored in the memory cell array 20 and may operate as a sense amplifier during a read operation to sense the data DATA stored in the memory cell array 20. The page buffer 34 may operate in response to a control signal PCTL provided from the control logic 38.

The data input-output circuit 36 may be connected to the page buffer 34 through data lines DLs. During a program operation, the data input-output circuit 36 may receive the data DATA from a memory controller (not shown) and provide the data DATA to the page buffer 34 as program data based on a column address C_ADDR provided from the control logic 38. During a read operation, the data input-output circuit 36 may provide the data DATA stored in the page buffer 34 to the memory controller as read data based on the column address C_ADDR provided from the control logic 38.

The data input-output circuit 36 may provide an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input-output circuit 36. The control logic 38 may generate various kinds of internal control signals to be used inside the semiconductor device 10, in response to the control signal CTRL. For example, the control logic 38 may adjust voltage levels to be provided to the word lines WL and the bit lines BL during a memory operation, such as a program operation and an erase operation.

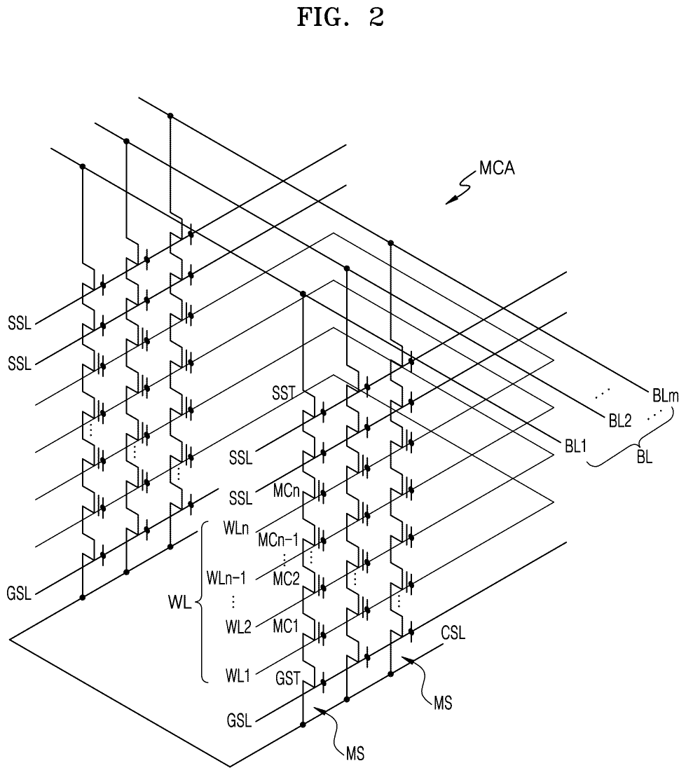

FIG. 2 is a circuit diagram illustrating a memory block according to embodiments.

Referring to FIG. 2, a memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn−1, and WLn), at least one string select line SSL, at least one ground select line GSL, and a common source line CSL. The plurality of memory cell strings MS may be formed between the plurality of bit lines BL (BL1, BL2, . . . , and BLm) and the common source line CSL. Although FIG. 2 shows that each of the plurality of memory cell strings MS includes two string select lines SSL, the technical idea of the inventive concept is not limited thereto. For example, each of the plurality of memory cell strings MS may include one string select line SSL.

Each of the plurality of memory cell strings MS may include a string select transistor SST, a ground select transistor GST, and a plurality of memory cell transistors MC1, MC2, . . . , MCn−1, and MCn. A drain region of the string select transistor SST may be connected to a bit line BL (BL1, BL2, . . . , or BLm), and a source region of the ground select transistor GST may be connected to the common source line CSL. The common source line CSL may be a region to which source regions of a plurality of ground select transistors GST are commonly connected.

The string select transistor SST may be connected to a string select line SSL, and the ground select transistor GST may be connected to a ground select line GSL. The plurality of memory cell transistors MC1, MC2, . . . , MCn−1, and MCn may be connected to the plurality of word lines WL (WL1, WL2, . . . , WLn−1, and WLn), respectively.

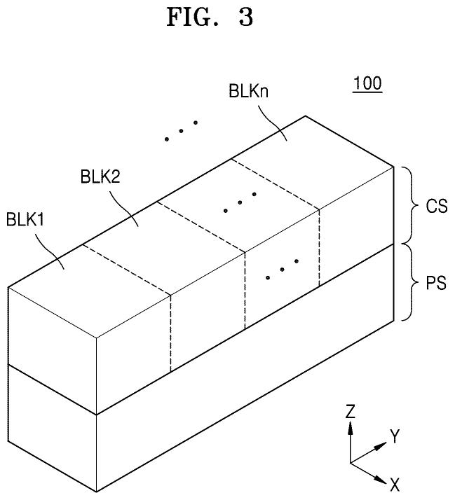

FIG. 3 is a perspective view illustrating a representative structure of a semiconductor device 100 according to embodiments.

Referring to FIG. 3, the semiconductor device 100 may include a peripheral circuit structure PS and a cell structure CS on the peripheral circuit structure PS.

The peripheral circuit structure PS may include the peripheral circuit 30 described with reference to FIG. 1. The cell structure CS may include the memory cell array 20 described with reference to FIG. 1.

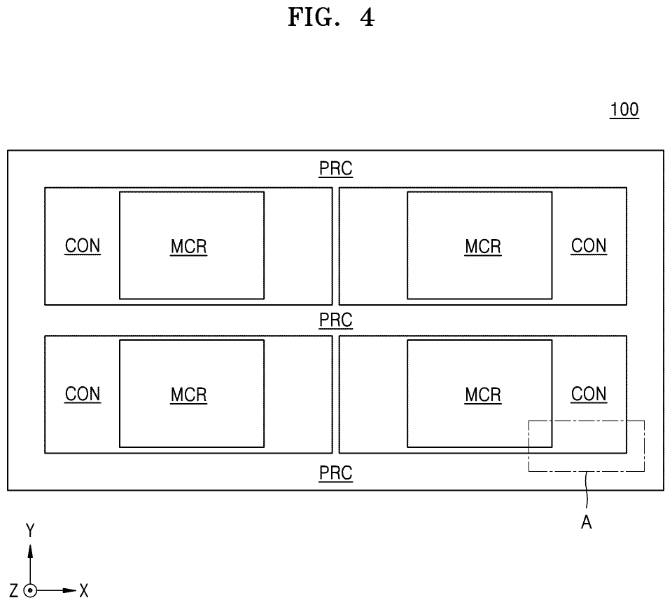

The cell structure CS may include the plurality of memory cell blocks BLK1, BLK2, and BLKn. Each of the plurality of memory cell blocks BLK1, BLK2, . . . , and BLKn may include three-dimensionally arranged memory cells. For example, the plurality of memory cell blocks BLK1, BLK2, . . . , and BLKn may be sequentially arranged in a second horizontal direction (the Y direction). The definition of a first horizontal direction (the X direction), the second horizontal direction (the Y direction), and a vertical direction (the Z direction) in FIG. 3 are the same as the definition of the first horizontal direction (the X direction), the second horizontal direction (the Y direction), and the vertical direction (the Z direction) in FIGS. 4 to 7.

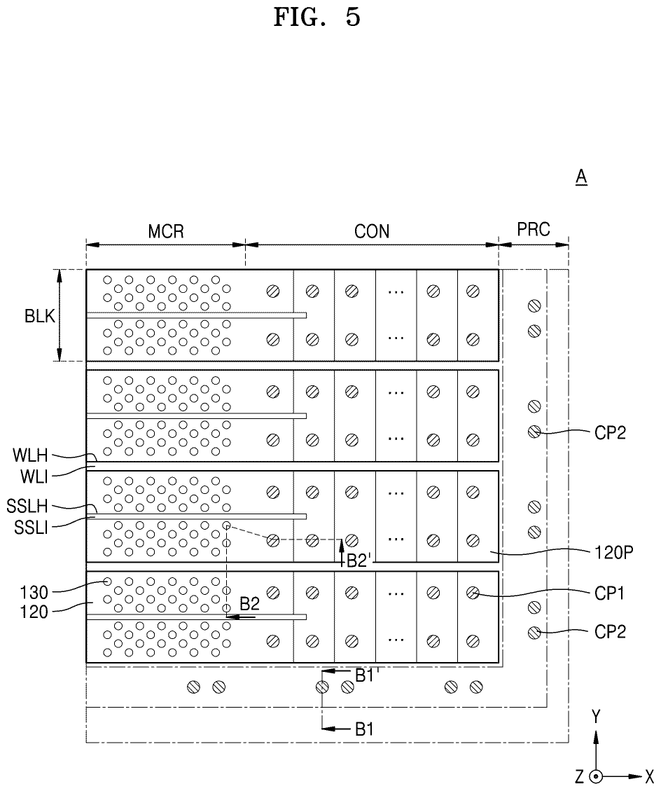

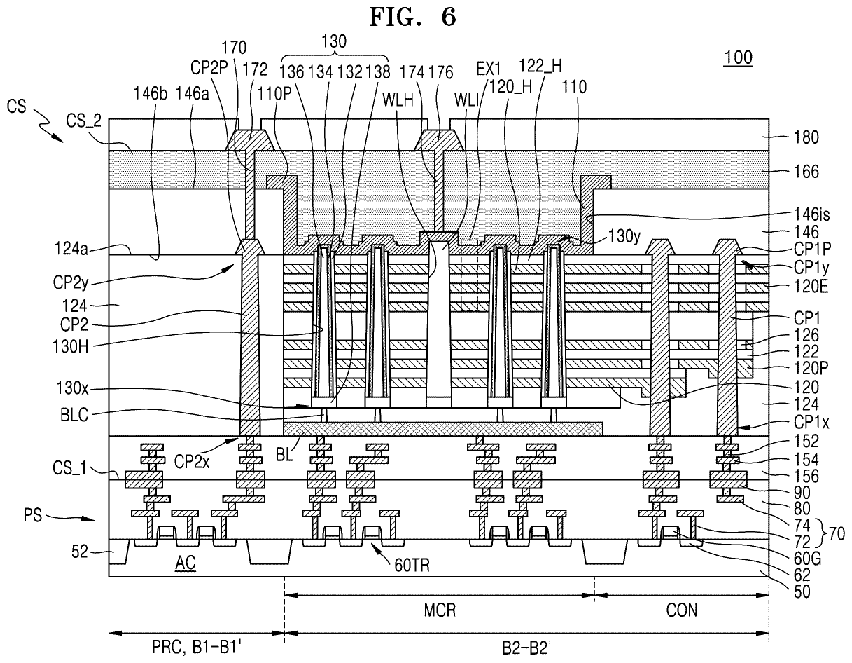

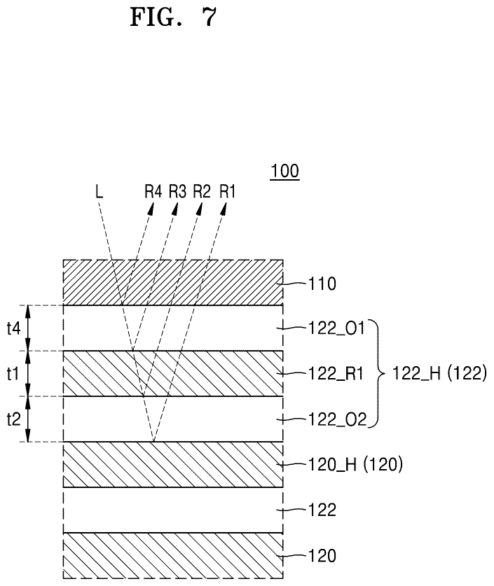

FIG. 4 is a plan layout diagram of the semiconductor device 100 of FIG. 3. FIG. 5 is an enlarged layout diagram of a portion A of the semiconductor device 100 of FIG. 4. FIG. 6 is a cross-sectional view illustrating the semiconductor device 100 of FIG. 5, taken along lines B1-B1′ and B2-B2′ of FIG. 5. FIG. 7 is an enlarged view illustrating a portion EX1 of the semiconductor device 100 of FIG. 6.

Referring to FIGS. 4 to 7, the semiconductor device 100 may include the cell structure CS and the peripheral circuit structure PS overlapping each other in the vertical direction (the Z direction). The cell structure CS may include the memory cell array 20 described with reference to FIG. 1, and the peripheral circuit structure PS may include the peripheral circuit 30 described with reference to FIG. 1. The cell structure CS may correspond to the cell structure CS of FIG. 3, and the peripheral circuit structure PS may correspond to the peripheral circuit structure PS of FIG. 3.

In the specification, it is defined that the first horizontal direction (the X direction) is one direction parallel to the upper surface of a substrate 50, the second horizontal direction (the Y direction) is a direction parallel to the upper surface of the substrate 50 and intersecting the first horizontal direction (the X direction), and the vertical direction (the Z direction) is a direction perpendicular to the upper surface of the substrate 50.

The peripheral circuit structure PS may include the peripheral circuit transistor 60TR and the peripheral circuit wiring structure 70 on the substrate 50. In the substrate 50, the active region AC may be defined by the device isolation layer 52, and the plurality of peripheral circuit transistors 60TR may be formed on the active region AC. Each of the plurality of peripheral circuit transistors 60TR may include the peripheral circuit gate 60G and the source/drain regions 62 at opposite sides of the peripheral circuit gate 60G in a portion of the substrate 50.

The substrate 50 may include a semiconductor material, e.g., a Group IV semiconductor, a Group III-V compound semiconductor, or a Group II-VI oxide semiconductor. For example, the Group IV semiconductor may include silicon (Si), germanium (Ge), or SiGe. The substrate 50 may be provided as a bulk wafer or an epitaxial layer. In another embodiment, the substrate 50 may include a silicon-on-insulator (SOI) substrate or a germanium-on-insulator (GeOI) substrate.

The peripheral circuit wiring structure 70 may include a plurality of peripheral circuit contacts 72 and a plurality of peripheral circuit wiring layers 74. A first interlayer insulating layer 80 covering the plurality of peripheral circuit transistors 60TR and the peripheral circuit wiring structure 70 may be on the substrate 50. The plurality of peripheral circuit wiring layers 74 may have a multi-layer structure including a plurality of metal layers at different vertical levels. A connection pad 90 may be on the first interlayer insulating layer 80. The first interlayer insulating layer 80 may not cover the upper surface of the connection pad 90. The peripheral circuit structure PS may be electrically connected and bonded to the cell structure CS by the connection pad 90.

The cell structure CS may include a cell region MCR, a connection region CON, and a peripheral circuit connection region PRC. As shown in FIG. 4, the connection region CON may be beside the cell region MCR in the first horizontal direction (the X direction), and the peripheral circuit connection region PRC may surround the cell region MCR and the connection region CON.

The cell region MCR may be a region in which a memory cell block BLK including the plurality of memory cell strings MS (see FIG. 2) extending in the vertical direction (the Z direction) is arranged.

In the cell region MCR, a common source layer 110, gate electrodes 120, mold insulating layers 122, and a channel structure 130 may be arranged.

In the connection region CON, extension portions 120E and pad portions 120P connected to respective gate electrodes 120 may be arranged. In the connection region CON, a first plug CP1 penetrating extension portions 120E and a pad portion 120P and electrically connected to the pad portion 120P may be arranged. In the peripheral circuit connection region PRC, a second plug CP2 extending in the vertical direction (the Z direction) and electrically connected to the peripheral circuit wiring structure 70 may be arranged.

The cell structure CS may include a first surface CS_1 connected to the peripheral circuit structure PS and a second surface CS_2 that is opposite to the first surface CS_1. FIG. 6 shows that the first surface CS_1 of the cell structure CS is at a lower side of the cell structure CS and the second surface CS_2 of the cell structure CS is at an upper side of the cell structure CS. Herein, for convenience of description, as shown in FIG. 6, it is indicated that a portion of the cell structure CS closer to the first surface CS_1 is at a lower vertical level and a portion of the cell structure CS closer to the second surface CS_2 is at a higher vertical level.

In the cell region MCR, the gate electrodes 120 may be arranged to be spaced apart from each other in the vertical direction (the Z direction), and the gate electrodes 120 and the mold insulating layers 122 may be alternately stacked one by one in the vertical direction (the Z direction). An uppermost mold insulating layer 122_H that is uppermost among the mold insulating layers 122 may be on the upper surface of an uppermost gate electrode 120_H that is uppermost among the gate electrodes 120. The uppermost mold insulating layer 122_H may be between the common source layer 110 and the uppermost gate electrode 120_H. For example, the uppermost mold insulating layer 122_H that is the highest, in the vertical direction relative to the upper surface of the substrate 50, among the mold insulating layers 122 may be on the upper surface of an uppermost gate electrode 120_H that is the highest, in the vertical direction relative to the upper surface of the substrate 50, among the gate electrodes 120.

The gate electrodes 120 may extend to the connection region CON. Portions of the gate electrodes 120 in the connection region CON may be referred to as extension portions 120E. The extension portions 120E may have respective horizontal lengths gradually increasing in the direction from the first surface CS_1 to the second surface CS_2 of the cell structure CS (i.e., in the vertical direction (the Z direction) in FIG. 6). The extension portions 120E may have a stepped shape, and pad portions 120P may be connected to ends of the extension portions 120E, respectively. A pad portion 120P may be a portion of a gate electrode 120. Each of the pad portions 120P may have a greater thickness than each of the extension portions 120E in the vertical direction (the Z direction).

Although not shown, each of the gate electrodes 120 may include a buried conductive layer and a conductive barrier layer surrounding the upper surface, the lower surface, and the side surface of the buried conductive layer. For example, the buried conductive layer may include a metal, such as tungsten, nickel, cobalt, and tantalum, metal silicide, such as tungsten silicide, nickel silicide, cobalt silicide, and tantalum silicide, doped polysilicon, or a combination thereof. In some embodiments, the conductive barrier layer may include titanium nitride, tantalum nitride, tungsten nitride, or a combination thereof.

In embodiments, the gate electrodes 120 may correspond to the at least one ground select line GSL (see FIG. 2), the plurality of word lines WL (see FIG. 2), and the at least one string select line SSL (see FIG. 2) constituting a memory cell string MS (see FIG. 2). For example, the uppermost gate electrode 120_H may function as a ground select line GSL (see FIG. 2), two bottom gate electrodes 120 may function as string select lines SSL (see FIG. 2), and the remaining gate electrodes 120 may function as the plurality of word lines WL (see FIG. 2). Accordingly, a memory cell string MS (see FIG. 2), in which a ground select transistor GST (see FIG. 2), two string select transistors SST (see FIG. 2), and the plurality of memory cell transistors MC1, MC2, . . . , MCn−1, and MCn (see FIG. 2) therebetween are connected in series, may be provided. In some embodiments, at least one of the gate electrodes 120 may function as a dummy word line, and the inventive concept is not limited thereto.

A stack isolation insulating layer WLI may be in a stack isolation opening portion WLH penetrating the gate electrodes 120 and the mold insulating layers 122 and extending in the vertical direction (the Z direction). The stack isolation insulating layer WLI may have an upper surface at a higher vertical level than that of the uppermost gate electrode 120_H and protrude in the vertical direction (the Z direction) from the uppermost gate electrode 120_H.

As shown in FIG. 5, gate electrodes 120 between a pair of stack isolation opening portions WLH may constitute one block BLK. At least one gate electrode 120 (e.g., the uppermost gate electrode 120_H) in one block BLK may be divided into two gate electrodes 120 by a string isolation opening portion SSLH. A string isolation insulating layer SSLI may be in the string isolation opening portion SSLH.

A stack insulating layer 124 may surround the gate electrodes 120, the extension portions 120E, and the pad portions 120P in the connection region CON and the peripheral circuit connection region PRC. In a plan view, the stack insulating layer 124 may surround the gate electrodes 120. In the peripheral circuit connection region PRC, an upper surface 124a of the stack insulating layer 124 may have the same vertical level as the upper surface of the uppermost mold insulating layer 122_H at the uppermost among the mold insulating layers 122.

The channel structure 130 may extend in the vertical direction (the Z direction) through the gate electrodes 120 and the mold insulating layers 122 and may be connected to the common source layer 110.

The channel structure 130 may include a first end portion 130y protruding upward from the uppermost mold insulating layer 122_H and a second end portion 130x close to the peripheral circuit structure PS. In embodiments, the channel structure 130 may have a sidewall inclined such that the width of the second end portion 130x is greater than the width of the first end portion 130y. The second end portion 130x of the channel structure 130 may be electrically connected to a bit line BL via a bit line contact BLC, and the first end portion 130y of the channel structure 130 may be connected to the common source layer 110.

The channel structure 130 may be in a channel hole 130H extending in the vertical direction (the Z direction) through the gate electrodes 120 and the mold insulating layers 122 and include a gate insulating layer 132, a channel layer 134, a buried insulating layer 136, and a drain region 138. The channel layer 134 may have a cylindrical shape, the gate insulating layer 132 may be on the outer wall of the channel layer 134, and the buried insulating layer 136 may be on the inner wall of the channel layer 134. The gate insulating layer 132 may not be on the upper surface of the channel layer 134, for example, the upper surface of the channel layer 134 at the first end portion 130y of the channel structure 130.

Although not shown, the gate insulating layer 132 may have a structure sequentially including a tunneling dielectric layer, a charge storage layer, and a blocking dielectric layer on the outer wall of the channel layer 134. The relative thicknesses of the tunneling dielectric layer, the charge storage layer, and the blocking dielectric layer constituting the gate insulating layer 132 may be variously modified.

The tunneling dielectric layer may include silicon oxide, hafnium oxide, aluminum oxide, zirconium oxide, or tantalum oxide. The charge storage layer is a region in which electrons having passed through the tunneling dielectric layer from the channel layer 134 may be stored, and may include silicon nitride, boron nitride, silicon boron nitride, or impurity-doped polysilicon. The blocking dielectric layer may include silicon oxide, silicon nitride, or metal oxide having a greater dielectric constant than the silicon oxide. The metal oxide may include hafnium oxide, aluminum oxide, zirconium oxide, tantalum oxide, or a combination thereof.

The common source layer 110 may be on the uppermost mold insulating layer 122_H and connected to the first end portion 130y of the channel structure 130. The common source layer 110 may be conformally formed to cover the upper surface of the stack isolation insulating layer WLI. In a plan view, the common source layer 110 may be all over the cell region MCR.

In some embodiments, the semiconductor device 100 may further include an etching stop layer between the uppermost mold insulating layer 122_H and the common source layer 110. A portion of the common source layer 110 in contact with the etching stop layer may have an upper surface at a vertical level different from that of a portion of the common source layer 110 in contact with the first end portion 130y of the channel structure 130. In some embodiments, a portion of the common source layer 110 in contact with the stack isolation insulating layer WLI may have an upper surface at a vertical level different from that of the portion of the common source layer 110 in contact with the first end portion 130y of the channel structure 130.

In some embodiments, the common source layer 110 may conformally cover the upper surface of the channel layer 134 and the upper surface of the gate insulating layer 132. For example, the gate insulating layer 132 may be at a lower vertical level than the upper surface of the channel layer 134. Accordingly, the upper surface and a portion of the sidewall of the channel layer 134 may be covered by the common source layer 110, thereby ensuring a sufficient contact area between the channel layer 134 and the common source layer 110.

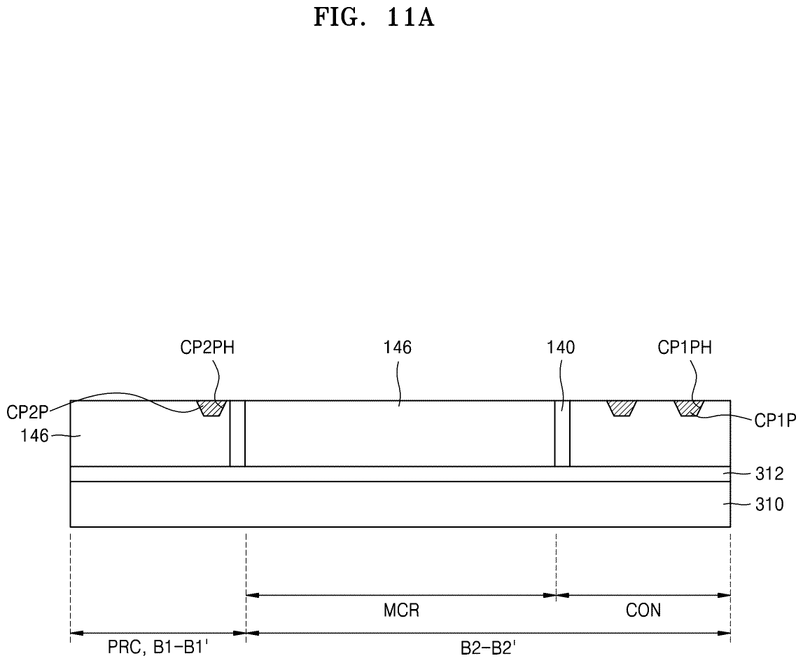

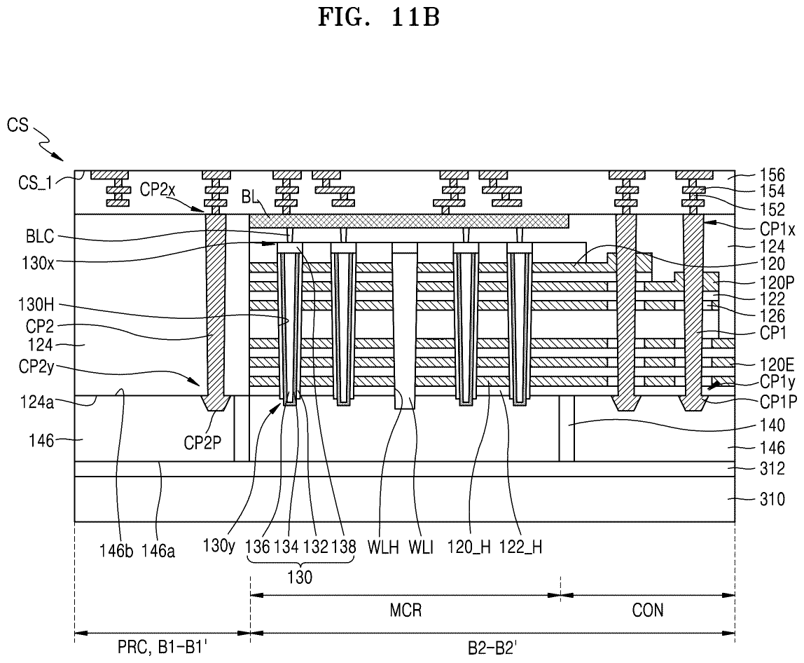

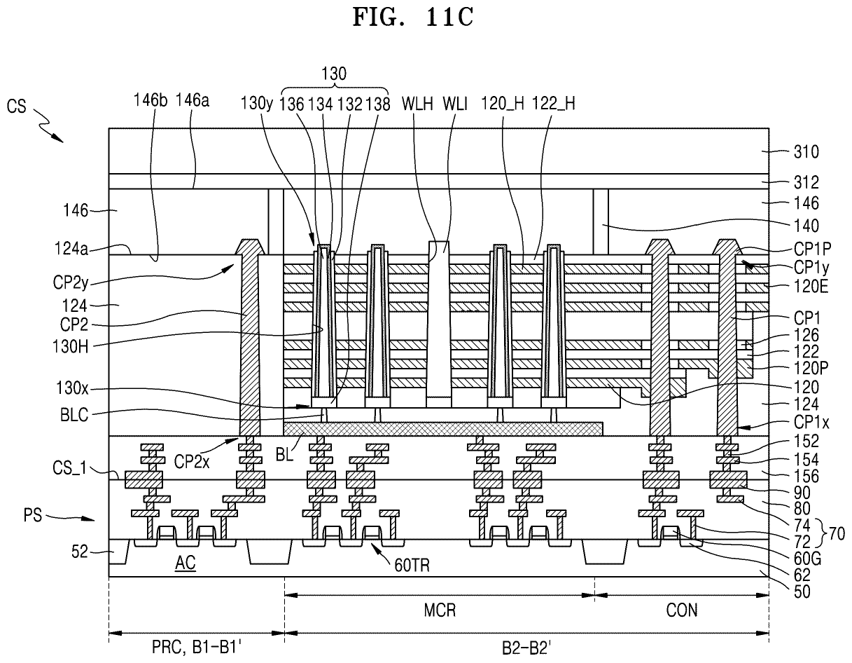

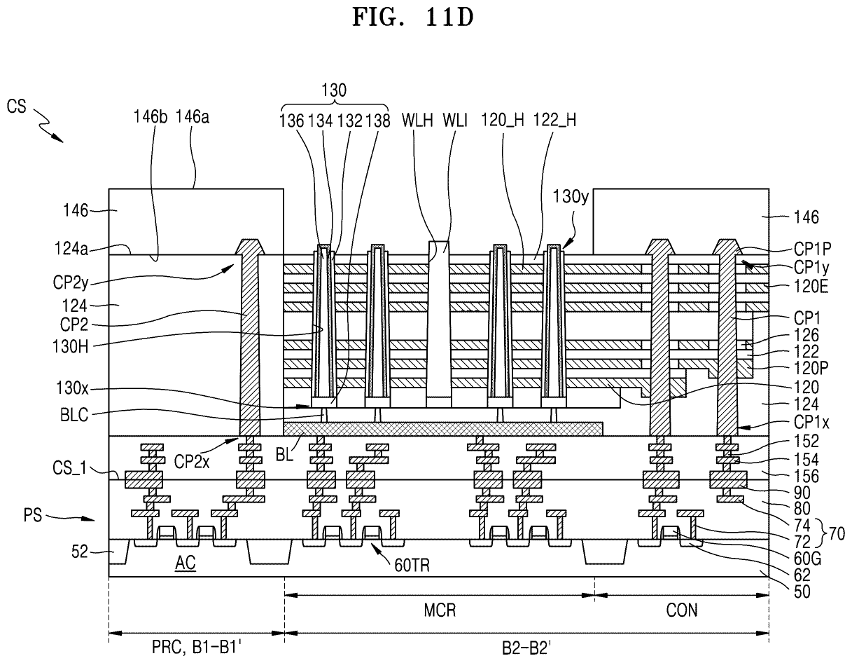

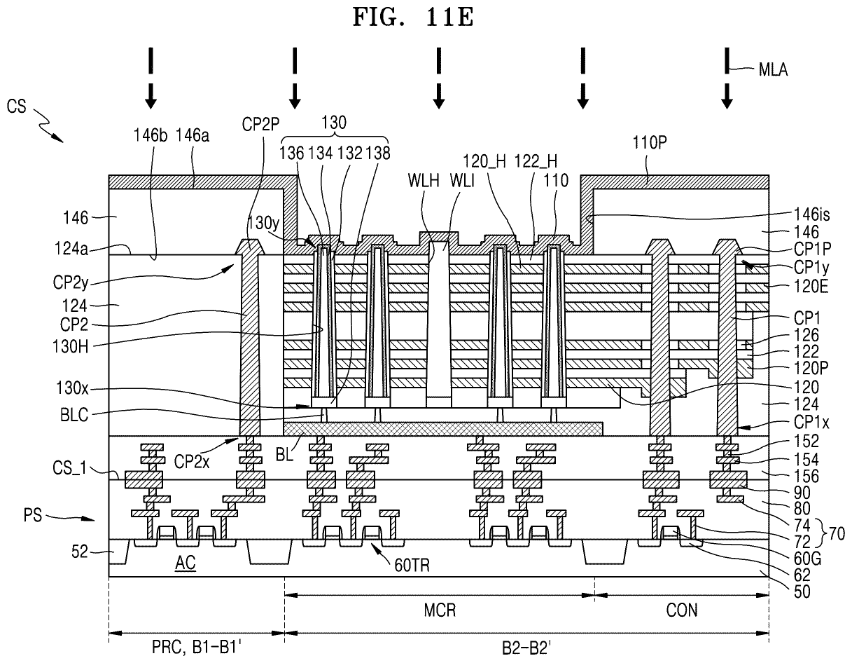

In some embodiments, the common source layer 110 may include polysilicon, and a melt laser annealing (MLA) process (see FIG. 11E) may be performed on the common source layer 110 such that the common source layer 110 has a relatively large grain size and/or relatively excellent crystal quality. In some embodiments, when the MLA process (see FIG. 11E) is performed on the common source layer 110, the etching stop layer may be crystallized together, and thus the etching stop layer may also have a relatively large grain size and/or relatively excellent crystal quality.

In some embodiments, after the MLA process (see FIG. 11E) is performed, the physical boundary between the etching stop layer and the common source layer 110 may not be identified.

In the connection region CON and the peripheral circuit connection region PRC, an upper insulating pattern 146 may be on the uppermost mold insulating layer 122_H among the mold insulating layers 122. In the connection region CON, the upper insulating pattern 146 may cover the upper surface of the uppermost mold insulating layer 122_H among the mold insulating layers 122 and a first landing pad CP1P. In the peripheral circuit connection region PRC, the upper insulating pattern 146 may cover the upper surface 124a of the stack insulating layer 124 and a second landing pad CP2P.

In a plan view, the upper insulating pattern 146 may surround the cell region MCR. An upper surface 146a of the upper insulating pattern 146 may be at a higher vertical level than the uppermost gate electrode 120_H. The upper insulating pattern 146 may include a silicon oxide layer, a silicon nitride layer, silicon oxynitride (SiON), silicon oxycarbonitride (SiOCN), silicon carbonitride (SiCN), or a combination thereof.

The common source layer 110 may extend along the inner sidewall 146 is of the upper insulating pattern 146. The common source layer 110 may extend along the upper surface 146a of the upper insulating pattern 146. The common source layer 110 may cover a portion of the upper surface 146a of the upper insulating pattern 146. A portion of the common source layer 110 extending on the upper insulating pattern 146 may be referred to as an edge portion 110P of the common source layer 110.

In the connection region CON, the first plug CP1 penetrating the extension portions 120E may be arranged. The first plug CP1 may penetrate a pad portion 120P of any one of the gate electrodes 120 and may be connected to the pad portion 120P. Insulating patterns 126 may be formed at positions vertically (in the Z direction) overlapping the pad portion 120P connected to the first plug CP1 and may be between the first plug CP1 and the extension portions 120E, respectively.

In embodiments, a third end portion CP1x of the first plug CP1 may be adjacent to the peripheral circuit structure PS, and a fourth end portion CP1y of the first plug CP1 may be opposite to the third end portion CP1x. The first plug CP1 may have a sidewall inclined such that the width of the third end portion CP1x is greater than the width of the fourth end portion CP1y. The fourth end portion CP1y of the first plug CP1 may be in contact with the first landing pad CP1P. At least a portion of the first landing pad CP1P may be covered by the upper insulating pattern 146.

Although not shown, in embodiments, the first plug CP1 may include a conductive buried layer and a thin barrier layer surrounding the upper surface and the sidewall of the conductive buried layer. For example, the conductive buried layer may include a metal, such as tungsten, nickel, cobalt, and tantalum, metal silicide, such as tungsten silicide, nickel silicide, cobalt silicide, and tantalum silicide, doped polysilicon, or a combination thereof. The barrier layer may include titanium nitride, tantalum nitride, tungsten nitride, or a combination thereof.

In the peripheral circuit connection region PRC, the second plug CP2 penetrating the stack insulating layer 124 may be arranged. A fifth end portion CP2x of the second plug CP2 may be adjacent to the peripheral circuit structure PS, and a sixth end portion CP2y of the second plug CP2 may be opposite to the fifth end portion CP2x. The second plug CP2 may have a sidewall inclined such that the width of the fifth end portion CP2x is greater than the width of the sixth end portion CP2y.

The sixth end portion CP2y of the second plug CP2 may be in contact with the second landing pad CP2P. At least a portion of the second landing pad CP2P may be covered by the upper insulating pattern 146.

A connection via 152, a connection wiring layer 154, and a second interlayer insulating layer 156 surrounding the connection via 152 and the connection wiring layer 154 may be between the stack insulating layer 124 and the peripheral circuit structure PS. The connection via 152 and the connection wiring layer 154 may be provided with multiple layers so as to be at a plurality of vertical levels, and may be electrically connect the bit line BL, the first plug CP1, and the second plug CP2 to the peripheral circuit structure PS via the connection pad 90.

An upper interlayer insulating layer 166 may be on the common source layer 110 and the upper insulating pattern 146. A first rear via 170 penetrating the upper interlayer insulating layer 166 and the upper insulating pattern 146 may be arranged. A plurality of first rear vias 170 may be provided. For example, the first rear via 170 may extend into the upper insulating pattern 146 so as to be connected to the second plug CP2. The first rear via 170 may be connected to the second landing pad CP2P. A first rear pad 172 may be on the upper interlayer insulating layer 166. A plurality of first rear pads 172 may be provided. Each of the plurality of first rear pads 172 may be connected to a corresponding one of the plurality of first rear vias 170.

In the cell region MCR, a second rear via 174 penetrating the upper interlayer insulating layer 166 may be arranged. A plurality of second rear vias 174 may be provided. The second rear via 174 may be connected to the common source layer 110. A second rear pad 176 may be connected to the second rear via 174. A plurality of second rear pads 176 may be provided. A passivation layer 180 may be on the upper interlayer insulating layer 166, and an opening portion of the passivation layer 180 may expose the upper surface of the second rear pad 176. Another opening portion of the passivation layer 180 may expose the upper surface of the first rear pad 172.

Hereinafter, the uppermost mold insulating layer 122_H and the uppermost gate electrode 120_H are particularly described with reference to FIG. 7.

The uppermost mold insulating layer 122_H may include a first low-refractive-index layer 122_O1, a high-refractive-index layer 122_R1, and a second low-refractive-index layer 122_O2. The uppermost mold insulating layer 122_H may be between the common source layer 110 and the uppermost gate electrode 120_H. In some embodiments, the thickness of the uppermost mold insulating layer 122_H may be different from the thickness of each of the remaining mold insulating layers 122.

The first low-refractive-index layer 122_O1 may be on the lower surface of the common source layer 110, the high-refractive-index layer 122_R1 may be on the lower surface of the first low-refractive-index layer 122_O1, and the second low-refractive-index layer 122_O2 may be on the lower surface of the high-refractive-index layer 122_R1.

The refractive index of the first low-refractive-index layer 122_O1 on the lower surface of the common source layer 110 may be less than the refractive index of the common source layer 110. The refractive index of the high-refractive-index layer 122_R1 on the lower surface of the first low-refractive-index layer 122_O1 may be greater than the refractive index of the first low-refractive-index layer 122_O1. The refractive index of the second low-refractive-index layer 122_O2 on the lower surface of the high-refractive-index layer 122_R1 may be less than the refractive index of the high-refractive-index layer 122_R1. The refractive index of the uppermost gate electrode 120_H on the lower surface of the second low-refractive-index layer 122_O2 may be greater than the refractive index of the second low-refractive-index layer 122_O2.

In some embodiments, the uppermost mold insulating layer 122_H may include two materials having different refractive indices and alternately stacked. For example, the uppermost mold insulating layer 122_H may include a relatively low-refractive-index layer and a relatively high-refractive-index layer that are alternately stacked. For example, the refractive index of the first low-refractive-index layer 122_O1 may be substantially the same as the refractive index of the second low-refractive-index layer 122_O2. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

In some embodiments, the high-refractive-index layer 122_R1 may include silicon nitride, and the first low-refractive-index layer 122_O1 and the second low-refractive-index layer 122_O2 may include silicon oxide. A first thickness t1 of the high-refractive-index layer 122_R1 may be different from a second thickness t2 of the second low-refractive-index layer 122_O2. For example, the first thickness t1 of the high-refractive-index layer 122_R1 may be greater than the second thickness t2 of the second low-refractive-index layer 122_O2. For example, the first thickness t1 of the high-refractive-index layer 122_R1 may be about 60 nm to about 80 nm. The second thickness t2 of the second low-refractive-index layer 122_O2 may be about 85 nm to about 100 nm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Hereinafter, to perform an MLA process on the common source layer 110, incident light L may be incident onto the common source layer 110. In some embodiments, the incident light L may be visible light having a wavelength of 300 nm to 700 nm inclusive.

A portion of the incident light L incident onto the common source layer 110 may be reflected from the boundary of two layers having different refractive indices. For example, a portion of the incident light L may be reflected as first reflected light R1 from the boundary of the uppermost gate electrode 120_H and the second low-refractive-index layer 122_O2. Another portion of the incident light L may be reflected as second reflected light R2 from the boundary of the second low-refractive-index layer 122_O2 and the high-refractive-index layer 122_R1. Another portion of the incident light L may be reflected as third reflected light R3 from the boundary of the high-refractive-index layer 122_R1 and the first low-refractive-index layer 122_O1. Another portion of the incident light L may be reflected as fourth reflected light R4 from the boundary of the first low-refractive-index layer 122_O1 and the common source layer 110. Although not shown in FIG. 7, a portion of the incident light L may be reflected from the upper surface of the common source layer 110.

In some embodiments, the phase difference between the first reflected light R1 and the incident light L may be an odd multiple of half the wavelength of the incident light L. The phase difference between the second reflected light R2 and the incident light L may be an odd multiple of half the wavelength of the incident light L. The phase difference between the third reflected light R3 and the incident light L may be an odd multiple of half the wavelength of the incident light L. The phase difference between the fourth reflected light R4 and the incident light L may be an odd multiple of half the wavelength of the incident light L. For example, when each of the first reflected light R1, the second reflected light R2, the third reflected light R3, and the fourth reflected light R4 interferes with the incident light L, an offset phenomenon (i.e., a destructive interference) may occur.

In some embodiments, the phase difference between the first reflected light R1 and the second reflected light R2 may be an even multiple of half the wavelength of the incident light L. The phase difference between the third reflected light R3 and the fourth reflected light R4 may be an even multiple of half the wavelength of the incident light L. For example, the phase difference between the first reflected light R1 and the third reflected light R3 may be an even multiple of half the wavelength of the incident light L. The phase difference between two of the first reflected light R1, the second reflected light R2, the third reflected light R3, and the fourth reflected light R4 may be an integer multiple of the wavelength of the incident light L, and thus, when the first reflected light R1 to the fourth reflected light R4 interfere with each other, a reinforcement phenomenon (i.e., a constructive interference) may occur.

The incident light L may be offset by (i.e., may destructively interfere with) pieces of reflected light, and thus, the energy of the incident light L arriving at the uppermost gate electrode 120_H may be reduced. Therefore, during an MLA process, an increase in the temperature of the gate electrodes 120 may be suppressed to particularly suppress an increase of the temperature of the uppermost gate electrode 120_H, thereby improving the reliability of the semiconductor device 100.

Hereinafter, based on when the wavelength of the incident light L in a medium of which the refractive index is 1 is λ, the refractive index of the high-refractive-index layer 122_R1 is n₁ (n₁ is 1 or greater), the refractive index of the second low-refractive-index layer 122_O2 is n₂ (n₂ is 1 or greater), and the refractive index of the first low-refractive-index layer 122_O1 is n₄ (n₄ is 1 or greater), the first thickness t1 of the high-refractive-index layer 122_R1, the second thickness t2 of the second low-refractive-index layer 122_O2, and a fourth thickness t4 of the first low-refractive-index layer 122_O1 are described.

The first thickness t1 of the high-refractive-index layer 122_R1 may have a value of t₁ satisfying [Equation 1] below.

$${t}_{1} = {A}_{1} * ( \frac{λ}{4 {n}_{1}} ) , {A}_{1} is an odd number \qquad [ Equation 1 ]$$

The second thickness t2 of the second low-refractive-index layer 122_O2 may have a value of t₂ satisfying [Equation 2] below.

$${t}_{2} = {A}_{2} * ( \frac{λ}{4 {n}_{2}} ) , {A}_{2} is an odd number \qquad [ Equation 2 ]$$

In some embodiments, the fourth thickness t4 of the first low-refractive-index layer 122_O1 may have a value of t₄ satisfying [Equation 4] below.

$${t}_{4} = {A}_{4} * ( \frac{λ}{4 {n}_{4}} ) , {A}_{4} is an odd number \qquad [ Equation 4 ]$$

In some embodiments, A₁, A₂, and A₄ may be different numbers. For example, the large/small relation of t₁, t₂, and t₄ may depend on the large/small relation of A₁, A₂, and A₄. For example, the relative size of t₁, t₂, and t₄ may depend on the relative size of A₁, A₂, and A₄. In some embodiments, the wavelength 1 of the incident light L may be 300 nm to 700 nm inclusive.

In some embodiments, the second low-refractive-index layer 122_O2 may be configured such that the phase difference between the first reflected light R1 and the incident light L is an odd multiple of half the wavelength of the incident light L. The high-refractive-index layer 122_R1 may be configured such that the phase difference between the first reflected light R1 and the incident light L is an odd multiple of half the wavelength of the incident light L. The first low-refractive-index layer 122_O1 may be configured such that the phase difference between the third reflected light R3 and the incident light L is an odd multiple of half the wavelength of the incident light L. The common source layer 110 may be configured such that the phase difference between the fourth reflected light R4 and the incident light L is an odd multiple of half the wavelength of the incident light L.

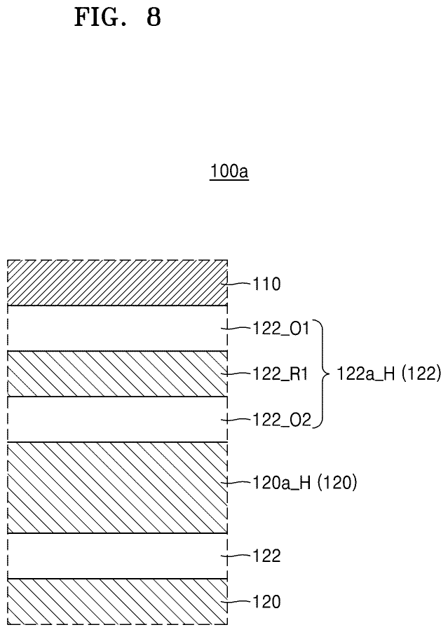

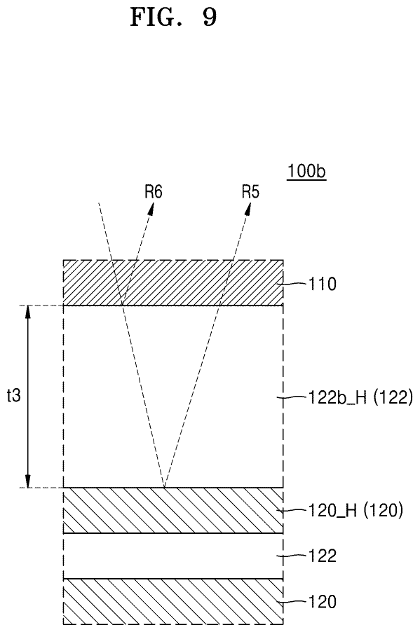

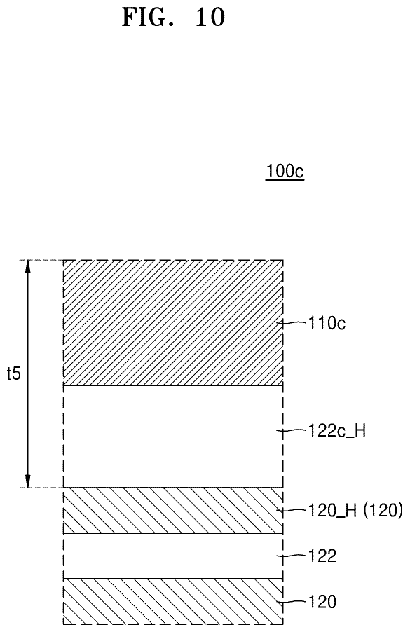

FIG. 8 is an enlarged view illustrating a portion of a semiconductor device 100a according to embodiments. FIG. 9 is an enlarged view illustrating a portion of a semiconductor device 100b according to embodiments. FIG. 10 is an enlarged view illustrating a portion of a semiconductor device 100c according to embodiments.

Most components constituting the semiconductor devices 100a, 100b, and 100c to be described below and materials forming the components are substantially the same as or similar to those described above with reference to FIGS. 1 to 7. Therefore, for convenience of description, differences between the semiconductor devices 100a, 100b, and 100c of FIGS. 8 to 10 and the semiconductor device 100 of FIG. 7 are mainly described.

Referring to FIG. 8, the semiconductor device 100a may include the gate electrodes 120 and the mold insulating layers 122 alternately stacked one by one and the common source layer 110 on the uppermost mold insulating layer 122a_H. The uppermost mold insulating layer 122a_H may be between the uppermost gate electrode 120a_H and the common source layer 110.

The thickness of the uppermost gate electrode 120a_H may be different from the thickness of each of the remaining gate electrodes 120. For example, the thickness of the uppermost gate electrode 120a_H may be greater than the thickness of each of the remaining gate electrodes 120. For example, during an MLA process, the uppermost gate electrode 120a_H may receive greater energy than each of the remaining gate electrodes 120. Accordingly, the uppermost gate electrode 120a_H may have a greater void occurrence probability than each of the remaining gate electrodes 120.

By making the thickness of the uppermost gate electrode 120a_H greater than the thickness of each of the remaining gate electrodes 120, an increase in the temperature of the uppermost gate electrode 120a_H may be suppressed during an MLA process. For example, as the thickness of the uppermost gate electrode 120a_H increases, an increase in the temperature of the uppermost gate electrode 120a_H may be reduced when the same energy is applied to the uppermost gate electrode 120a_H during an MLA process. Accordingly, the thickness of the uppermost gate electrode 120a_H may be increased to suppress a phenomenon that a void occurs in the uppermost gate electrode 120a_H during an MLA process.

Referring to FIG. 9, an uppermost mold insulating layer 122b_H may have a single-layer structure. For example, the uppermost mold insulating layer 122b_H may not include the high-refractive-index layer 122_R1 (see FIG. 7) and may include the second low-refractive-index layer 122_O2 (see FIG. 7) only.

The refractive index of the uppermost mold insulating layer 122b_H may be less than the refractive index of the common source layer 110. The refractive index of the uppermost mold insulating layer 122b_H may be less than the refractive index of the uppermost gate electrode 120_H.

A third thickness t3 of the uppermost mold insulating layer 122b_H may be different from the thickness of each of the remaining mold insulating layers 122 among the mold insulating layers 122. The third thickness t3 of the uppermost mold insulating layer 122b_H may be greater than the thickness of each of the remaining mold insulating layers 122.

In some embodiments, when the incident light L is incident onto the common source layer 110, a portion of the incident light L may be reflected as fifth reflected light R5 from the boundary of the uppermost gate electrode 120_H and the uppermost mold insulating layer 122b_H. Another portion of the incident light L may be reflected as sixth reflected light R6 from the boundary of the uppermost mold insulating layer 122b_H and the common source layer 110.

The phase difference between the fifth reflected light R5 and the incident light L may be an odd multiple of half the wavelength of the incident light L. The phase difference between the sixth reflected light R6 and the incident light L may be an odd multiple of half the wavelength of the incident light L. In some embodiments, the phase difference between the fifth reflected light R5 and the sixth reflected light R6 may be an even multiple of half the wavelength of the incident light L.

For example, when each of the fifth reflected light R5 and the sixth reflected light R6 interferes with the incident light L, the incident light L may be offset (i.e., may destructively interfere with each of the fifth reflected light R5 and the sixth reflected light R6) due to the phase difference between the incident light L and each of the fifth reflected light R5 and the sixth reflected light R6. Accordingly, the intensity of the incident light L may be reduced, thereby reducing an amount of the incident light L arriving at the uppermost gate electrode 120_H. The incident light L arriving at the uppermost gate electrode 120_H may be reduced to suppress a phenomenon that a void occurs in the uppermost gate electrode 120_H during an MLA process.

Based on when the wavelength of the incident light L in a medium of which the refractive index is 1 is λ and the refractive index of the uppermost mold insulating layer 122b_H is n₃ (n₃ is 1 or greater), the third thickness t3 of the uppermost mold insulating layer 122b_H is described.

The third thickness t3 of the uppermost mold insulating layer 122b_H may have a value of t₃ satisfying [Equation 3] below.

$${t}_{3} = B * ( \frac{λ}{4 {n}_{3}} ) , B is an even number \qquad [ Equation 3 ]$$

For example, when the incident light L is reflected from the boundary of the uppermost mold insulating layer 122b_H and the uppermost gate electrode 120_H, fixed end reflection may occur such that the phase of the incident light L may be inverted. Therefore, when it is configured that twice the third thickness t3 of the uppermost mold insulating layer 122b_H is an even multiple of half the wavelength of the incident light L, the phase difference between the fifth reflected light R5 and the incident light L may be an odd multiple of half the wavelength of the incident light L.

In some embodiments, the uppermost mold insulating layer 122b_H may be configured such that the phase difference between the fifth reflected light R5 and the incident light L is an odd multiple of half the wavelength of the incident light L. The common source layer 110 may be configured such that the phase difference between the sixth reflected light R6 and the incident light L is an odd multiple of half the wavelength of the incident light L.

In some embodiments, the thickness of the common source layer 110 may be relatively increased such that a portion of the incident light L is absorbed in the common source layer 110. Accordingly, an MLA process may be performed at an increased temperature of the common source layer 110, and an amount of the incident light L arriving at the uppermost mold insulating layer 122b_H may also be reduced. For example, the thickness of the common source layer 110 may be about 100 nm to about 300 nm.

Referring to FIG. 10, the length from the lower surface of an uppermost mold insulating layer 122c_H to the upper surface of a common source layer 110c may be a fifth thickness t5. The fifth thickness t5 may be a sum of the thickness of the uppermost mold insulating layer 122c_H and the thickness of the common source layer 110c. For example, the fifth thickness t5 may be about 100 nm to about 300 nm.

In some embodiments, when the thickness of the uppermost mold insulating layer 122c_H is greater than 70 nm, the thickness of the common source layer 110c may be less than 50 nm. In some embodiments, when the thickness of the uppermost mold insulating layer 122c_H is less than 70 nm, the thickness of the common source layer 110c may be greater than 100 nm.

For example, by setting the fifth thickness t5 as a certain value, an amount of incident light arriving at the uppermost gate electrode 120_H beneath the uppermost mold insulating layer 122c_H out of the incident light incident onto the common source layer 110c may be reduced. For example, while the incident light passes through the common source layer 110c and the uppermost mold insulating layer 122c_H, a portion of the incident light may be absorbed in the common source layer 110c and the uppermost mold insulating layer 122c_H.

FIGS. 11A to 11E are cross-sectional views taken along lines B1-B1′ and B2-B2′ of FIG. 5 to illustrate a method of manufacturing a semiconductor device according to embodiments.

Referring to FIG. 11A, a buffer insulating layer 312 may be formed on a carrier substrate 310, and the upper insulating pattern 146 may be formed on the buffer insulating layer 312.

In embodiments, the carrier substrate 310 may include at least one of Si, Ge, SiGe, gallium arsenide (GaAs), indium gallium arsenide (InGaAs), aluminum gallium arsenide (AlGaAs), and a mixture thereof. The buffer insulating layer 312 may be formed using a combination of silicon oxide, a dual layer of silicon oxide and titanium nitride, or a dual layer of silicon oxide and silicon nitride. The upper insulating pattern 146 may include a silicon oxide layer, a silicon nitride layer, SiON, SiOCN, SiCN, or a combination thereof.

The cell region MCR, the connection region CON, and the peripheral circuit connection region PRC may be defined on the carrier substrate 310, and the upper insulating pattern 146 may be formed with a uniform height all over the cell region MCR, the connection region CON, and the peripheral circuit connection region PRC.

An insulating wall 140 may be formed by removing a portion of the upper insulating pattern 146. The insulating wall 140 may be formed at the boundary of the cell region MCR and the connection region CON, the boundary of the cell region MCR and the peripheral circuit connection region PRC, and/or the boundary of the connection region CON and the peripheral circuit connection region PRC.

In the connection region CON, a first landing pad opening portion CP1PH may be formed by removing a portion of the upper insulating pattern 146 and the first landing pad CP1P may be formed in the first landing pad opening portion CP1PH. In the peripheral circuit connection region PRC, a second landing pad opening portion CP2PH may be formed by removing a portion of the upper insulating pattern 146 and the second landing pad CP2P may be formed in the second landing pad opening portion CP2PH.

In some embodiments, thereafter, an etching stop layer may be further formed on the upper insulating pattern 146 in the cell region MCR. In embodiments, the etching stop layer may be formed using polysilicon.

Referring to FIG. 11B, in the cell region MCR and the connection region CON, the gate electrodes 120 and the mold insulating layers 122 may be formed, and in the connection region CON, the extension portions 120E and the pad portion 120P connected to the gate electrodes 120 may be formed. In the cell region MCR, the channel structure 130 extending in the vertical direction (the Z direction) through the gate electrodes 120, and the bit line BL connected to the channel structure 130 may be formed.

A mold insulating layer formed on the upper insulating pattern 146 among the mold insulating layers 122 may be referred to as the uppermost mold insulating layer 122_H, and a gate electrode formed on the uppermost mold insulating layer 122_H among the gate electrodes 120 may be referred to as the uppermost gate electrode 120_H. In some embodiments, the uppermost mold insulating layer 122_H may include the uppermost mold insulating layer 122_H, 122b_H, or 122c_H described above. The uppermost gate electrode 120_H may include the uppermost gate electrode 120a_H described above.

Referring to FIGS. 5 and 11B, the stack isolation opening portion WLH extending in the first horizontal direction (the X direction) from the cell region MCR to the connection region CON may be formed. The stack isolation insulating layer WLI may be formed in the stack isolation opening portion WLH.

In the connection region CON, the first plug CP1 penetrating the extension portions 120E and the pad portion 120P may be formed, and in the peripheral circuit connection region PRC, the second plug CP2 penetrating the stack insulating layer 124 may be formed. The connection via 152 and the connection wiring layer 154 electrically connected to the bit line BL, the first plug CP1, and the second plug CP2, and the second interlayer insulating layer 156 may be formed.

In embodiments, in a process of forming the channel structure 130, the second end portion 130x of the channel structure 130 may be at a higher vertical level than the first end portion 130y thereof. The first end portion 130y of the channel structure 130 may be formed to extend into the upper insulating pattern 146 through the uppermost mold insulating layer 122_H.

In embodiments, in a process of forming the first plug CP1, the third end portion CP1x of the first plug CP1 may be greater than the fourth end portion CP1y thereof in width. The fourth end portion CP1y of the first plug CP1 may be connected to the first landing pad CP1P.

In embodiments, in a process of forming the second plug CP2, the fifth end portion CP2x of the second plug CP2 may be greater than the sixth end portion CP2y thereof in width. The sixth end portion CP2y of the second plug CP2 may be connected to the second landing pad CP2P.

The connection via 152, the connection wiring layer 154, and the second interlayer insulating layer 156 surrounding the connection via 152 and the connection wiring layer 154 may be formed on the stack insulating layer 124.

Referring to FIG. 11C, the peripheral circuit structure PS may be prepared. The peripheral circuit structure PS may include the peripheral circuit transistor 60TR and the peripheral circuit wiring structure 70 on the substrate 50. In the substrate 50, the active region AC may be defined by the device isolation layer 52, and the plurality of peripheral circuit transistors 60TR may be formed on the active region AC. Each of the plurality of peripheral circuit transistors 60TR may include the peripheral circuit gate 60G and the source/drain regions 62 at opposite sides of the peripheral circuit gate 60G in a portion of the substrate 50.

Thereafter, the peripheral circuit structure PS may be attached to the cell structure CS. The peripheral circuit structure PS may be attached to the cell structure CS by metal-oxide hybrid bonding through the connection pad 90 and the first and second interlayer insulating layers 80 and 156, but the inventive concept is not limited thereto.

Thereafter, the structure in which the peripheral circuit structure PS is attached to the cell structure CS may be upside down such that the carrier substrate 310 faces upward.

Referring to FIG. 11D, an etching process may be performed on the upper insulating pattern 146 of FIG. 11C. By the etching process, a portion of the upper insulating pattern 146 may be removed. For example, a portion of the upper insulating pattern 146 in the cell region MCR may be removed. By the etching process, the inner sidewall 146 is (see FIG. 6) of the upper insulating pattern 146 may be exposed. When the portion of the upper insulating pattern 146 is removed, the first end portion 130y of the channel structure 130 may be exposed to the outside.

Thereafter, a portion of the gate insulating layer 132 exposed at the first end portion 130y of the channel structure 130 may be removed, thereby exposing the upper surface of the channel layer 134. In some embodiments, a process of removing the gate insulating layer 132 may be performed, thereby exposing the upper surface of the uppermost mold insulating layer 122_H.

In some embodiments, an upper side of the gate insulating layer 132 may be further removed, thereby the gate insulating layer 132 being at a lower vertical level than the upper surface of the channel layer 134 and exposing the upper surface and a portion of the sidewall of the channel layer 134. In the process of removing the gate insulating layer 132, an upper side of the stack isolation insulating layer WLI may also be exposed and protrude upward from the uppermost mold insulating layer 122_H.

Referring to FIG. 11E, the common source layer 110 may be formed in the cell region MCR, the connection region CON, and the peripheral circuit connection region PRC. The common source layer 110 may be formed using polysilicon. For example, the common source layer 110 may be formed using polysilicon doped with n-type impurities. In some embodiments, the common source layer 110 may include the common source layer 110 or 110c described above.

In the cell region MCR, the common source layer 110 may be conformally formed on the exposed upper surfaces of the uppermost mold insulating layer 122_H and the channel layer 134.

The common source layer 110 may extend along the upper insulating pattern 146. In the connection region CON and the peripheral circuit connection region PRC, the common source layer 110 may be formed on the upper surface of the upper insulating pattern 146 that is relatively flat, and thus, the common source layer 110 may be formed to have a relatively flat upper surface level. The edge portion 110P of the common source layer 110 may be a portion of the common source layer 110 extending on the upper insulating pattern 146.

An MLA process may be performed on the common source layer 110. In embodiments, the MLA process may be performed to improve the crystallization of the common source layer 110 in the cell region MCR, increase the grain size of the common source layer 110, or reduce the resistance of the common source layer 110. In some embodiments, after the MLA process is performed, the physical boundary between the etching stop layer and the common source layer 110 may not be identified.

When the MLA process is performed on the common source layer 110, the common source layer 110 and the uppermost mold insulating layer 122_H may have a particular configuration to suppress transmission of heat due to incident light to the uppermost mold insulating layer 122_H.

In some embodiments, the wavelength of the incident light used in the MLA process may be about 300 nm to about 700 nm. In some embodiments, the full width at half maximum (FWHM) of the incident light used in the MLA process may be about 15 nm to about 60 nm. In some embodiments, per-incident area power of the incident light used in the MLA process may be about 200 mJ/cm² to about 1200 mJ/cm².

Referring back to FIG. 6, a portion of the common source layer 110 in the connection region CON and the peripheral circuit connection region PRC may be removed. In embodiments, in the connection region CON and the peripheral circuit connection region PRC, the common source layer 110 is formed on the relatively flat upper surface of the cover insulating layer 148, and thus the difficulty of a process of removing the common source layer 110 may be reduced.

In some embodiments, the edge portion 110P of the common source layer 110 may extend on the inner sidewall 146 is of the upper insulating pattern 146. The edge portion 110P of the common source layer 110 may further extend on the upper surface of the upper insulating pattern 146. Accordingly, there may occur a vertical level difference between a center portion of the common source layer 110 and the edge portion 110P of the common source layer 110.

The upper interlayer insulating layer 166 may be formed on the common source layer 110 and the upper insulating pattern 146. Thereafter, in the peripheral circuit connection region PRC, the first rear via 170 penetrating the upper interlayer insulating layer 166 and the upper insulating pattern 146 may be formed. For example, the first rear via 170 may extend into the upper insulating pattern 146. The first rear via 170 may be connected to the second landing pad CP2P. In the cell region MCR, the second rear via 174 penetrating the upper interlayer insulating layer 166 may be formed. The second rear via 174 may be connected to the common source layer 110.

On the upper interlayer insulating layer 166, the first rear pad 172 connected to the first rear via 170 and the second rear pad 176 connected to the second rear via 174 may be formed. Thereafter, the passivation layer 180 covering the first and second rear pads 172 and 176 may be formed on the upper interlayer insulating layer 166, and opening portions may be formed in the passivation layer 180 to expose the upper surfaces of the first and second rear pads 172 and 176 therethrough.

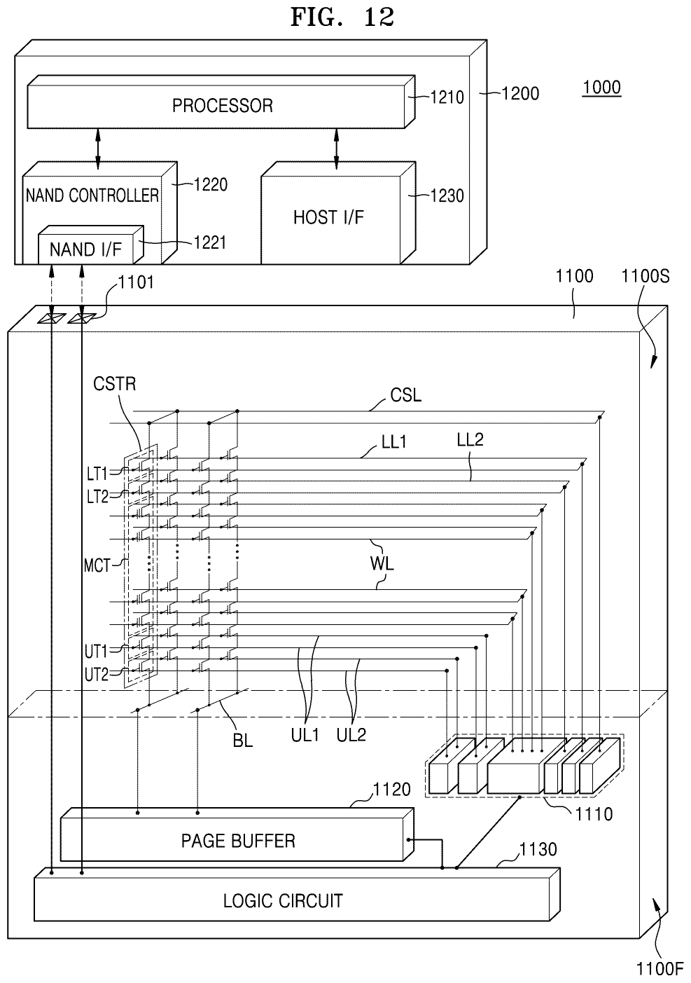

FIG. 12 is a block diagram illustrating a data storage system 1000 including a semiconductor device according to embodiments.

Referring to FIG. 12, the data storage system 1000 may include one or more semiconductor devices 1100 and a memory controller 1200 electrically connected to the one or more semiconductor devices 1100. The data storage system 1000 may be, for example, a solid state drive (SSD) device, a universal serial bus (USB) device, a computing system, a medical device, or a communication device including at least one semiconductor device 1100.

A semiconductor device 1100 may be a non-volatile memory device, and for example, the semiconductor device 1100 may be a NAND flash semiconductor device including one of the semiconductor devices 10, 100, 100a, 100b, and 100c described above with reference to FIGS. 1 to 10. The semiconductor device 1100 may include a first structure 1100F and a second structure 1100S on the first structure 1100F. The first structure 1100F may be the peripheral circuit structure PS (see FIG. 3) including a row decoder 1110, a page buffer 1120, and a logic circuit 1130.

The second structure 1100S may be the memory cell structure CS (see FIG. 3) including a plurality of bit lines BL, the common source line CSL, a plurality of word lines WL, first and second string select lines UL1 and UL2, first and second ground select lines LL1 and LL2, and a plurality of memory cell strings CSTR between the plurality of bit lines BL and the common source line CSL.

In the second structure 1100S, each of the plurality of memory cell strings CSTR may include ground select transistors LT1 and LT2 adjacent to the common source line CSL, string select transistors UT1 and UT2 adjacent to a bit line BL, and a plurality of memory cell transistors MCT between the ground select transistors LT1 and LT2 and the string select transistors UT1 and UT2. The number of ground select transistors (e.g., LT1 and LT2) and the number of string select transistors (e.g., UT1 and UT2) may be variously modified according to embodiments.

In embodiments, the first and second ground select lines LL1 and LL2 may be connected to the gate electrodes of the ground select transistors LT1 and LT2, respectively. The plurality of word lines WL may be connected to the gate electrodes of the plurality of memory cell transistors MCT, respectively. The first and second string select lines UL1 and UL2 may be connected to the gate electrodes of the string select transistors UT1 and UT2, respectively.

The common source line CSL, the first and second ground select lines LL1 and LL2, the plurality of word lines WL, and the first and second string select lines UL1 and UL2 may be connected to the row decoder 1110. The plurality of bit lines BL may be electrically connected to the page buffer 1120.

The semiconductor device 1100 may communicate with the memory controller 1200 through input-output pads 1101 electrically connected to the logic circuit 1130. The input-output pads 1101 may be electrically connected to the logic circuit 1130.

The memory controller 1200 may include a processor 1210, a NAND controller 1220, and a host interface 1230. In some embodiments, the data storage system 1000 may include a plurality of semiconductor devices 1100, and in this case, the memory controller 1200 may control the plurality of semiconductor devices 1100.

The processor 1210 may control a general operation of the data storage system 1000 including the memory controller 1200. The processor 1210 may operate according to certain firmware and control the NAND controller 1220 to access the semiconductor device 1100. The NAND controller 1220 may include a NAND interface 1221 configured to process communication with the semiconductor device 1100. Through the NAND interface 1221, a control command for controlling the semiconductor device 1100, data to be written on the plurality of memory cell transistors MCT in the semiconductor device 1100, or data read from the plurality of memory cell transistors MCT in the semiconductor device 1100 may be transferred. The host interface 1230 may provide a communication function between the data storage system 1000 and an external host. When a control command is received from the external host through the host interface 1230, the processor 1210 may control the semiconductor device 1100 in response to the control command.

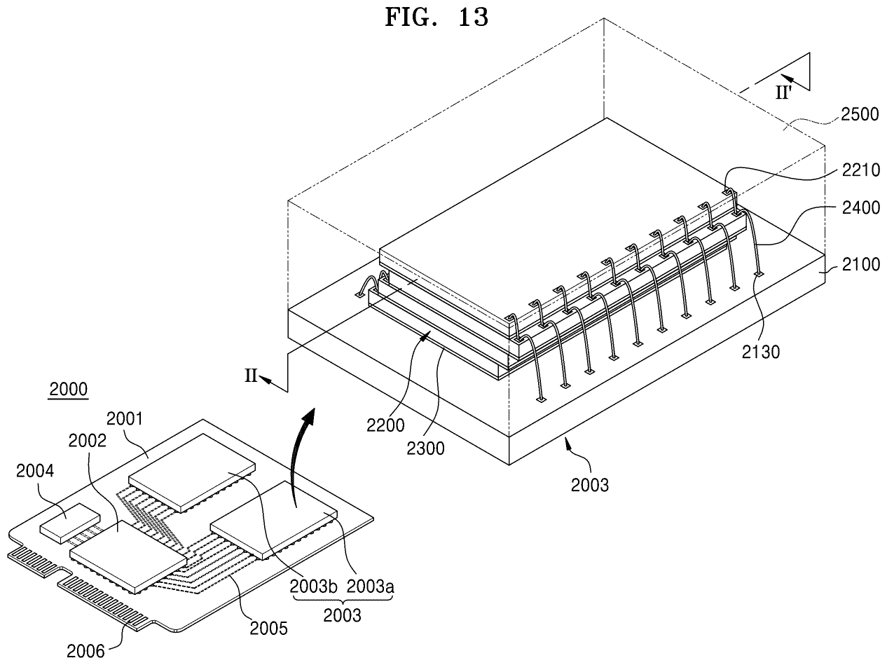

FIG. 13 is a perspective view illustrating a data storage system 2000 including a semiconductor device according to embodiments.

Referring to FIG. 13, the data storage system 2000 according to an embodiment may include a main substrate 2001 and a memory controller 2002, a semiconductor package 2003, and dynamic random access memory (DRAM) 2004, which are mounted on the main substrate 2001. The semiconductor package 2003 and the DRAM 2004 may be connected to the memory controller 2002 through a plurality of wiring patterns 2005 formed on the main substrate 2001.

The main substrate 2001 may include a connector 2006 including a plurality of pins coupled to an external host. The number and the arrangement of pins in the connector 2006 may vary according to a communication interface between the data storage system 2000 and the external host. In embodiments, the data storage system 2000 may communicate with the external host according to any one of interfaces, such as a USB interface, a peripheral component interconnect express (PCI-Express) interface, a serial advanced technology attachment (SATA) interface, and an M-Phy interface for a universal flash storage (UFS). In embodiments, the data storage system 2000 may operate by power received from the external host through the connector 2006. The data storage system 2000 may further include a power management integrated circuit (PMIC) configured to distribute the power received from the external host to the memory controller 2002 and the semiconductor package 2003.

The memory controller 2002 may write or read data on or from the semiconductor package 2003 and improve the operating speed of the data storage system 2000.

The DRAM 2004 may be a buffer memory configured to mitigate the speed difference between the semiconductor package 2003, which is a data storage space, and the external host. The DRAM 2004 included in the data storage system 2000 may operate as a kind of cache memory and provide a space in which data is temporarily stored in a control operation on the semiconductor package 2003. When the DRAM 2004 is included in the data storage system 2000, the memory controller 2002 may further include a DRAM controller configured to control the DRAM 2004 in addition to a NAND controller configured to control the semiconductor package 2003.

The semiconductor package 2003 may include first and second semiconductor packages 2003a and 2003b separated from each other. Each of the first and second semiconductor packages 2003a and 2003b may include a plurality of semiconductor chips 2200. Each of the first and second semiconductor packages 2003a and 2003b may include a package substrate 2100, the plurality of semiconductor chips 2200 on the package substrate 2100, an adhesive layer 2300 beneath each of the plurality of semiconductor chips 2200, a plurality of connection structures 2400 electrically connecting the plurality of semiconductor chips 2200 to the package substrate 2100, and a molding layer 2500 covering the plurality of semiconductor chips 2200 and the plurality of connection structures 2400 on the package substrate 2100.

The package substrate 2100 may be a printed circuit board including a plurality of package upper pads 2130. Each of the plurality of semiconductor chips 2200 may include input-output pads 2210. The input-output pads 2210 may correspond to the input-output pads 1101 of FIG. 12. Each of the plurality of semiconductor chips 2200 may include at least one of the semiconductor devices 10, 100, 100a, 100b, and 100c described above with reference to FIGS. 1 to 10.

In embodiments, the plurality of connection structures 2400 may be bonding wires electrically connecting the input-output pads 2201 to the plurality of package upper pads 2130. Therefore, in the first and second semiconductor packages 2003a and 2003b, the plurality of semiconductor chips 2200 may be electrically connected to each other by a bonding wire scheme and electrically connected to the plurality of package upper pads 2130 of the package substrate 2100. In embodiments, in the first and second semiconductor packages 2003a and 2003b, the plurality of semiconductor chips 2200 may be electrically connected to each other through a connection structure including through silicon vias (TSVs) instead of the plurality of connection structures 2400 of the bonding wire scheme.

In embodiments, the memory controller 2002 and the plurality of semiconductor chips 2200 may be included in one package. In embodiments, the memory controller 2002 and the plurality of semiconductor chips 2200 may be mounted on a separate interposer substrate other than the main substrate 2001, and the memory controller 2002 may be connected to the plurality of semiconductor chips 2200 through wirings formed on the interposer substrate.

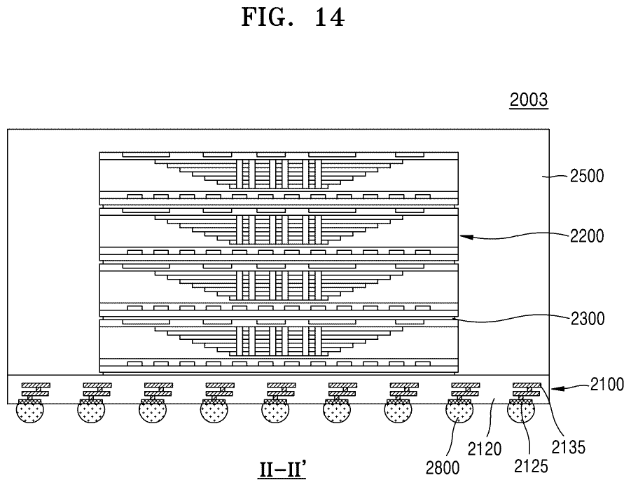

FIG. 14 is a cross-sectional view illustrating the semiconductor package 2003 according to embodiments, taken along line II-II′ of FIG. 13.

Referring to FIG. 14, in the semiconductor package 2003, the package substrate 2100 may be a printed circuit board. The package substrate 2100 may include a package substrate body part 2120, the plurality of package upper pads 2130 (see FIG. 13) on the upper surface of the package substrate body part 2120, a plurality of lower pads 2125 disposed on or exposed through the lower surface of the package substrate body part 2120, and a plurality of internal wirings 2135 inside the package substrate body part 2120 to electrically connect the plurality of package upper pads 2130 (see FIG. 13) to the plurality of lower pads 2125. As shown in FIG. 13, the plurality of package upper pads 2130 may be electrically connected to the plurality of connection structures 2400. As shown in FIG. 14, the plurality of lower pads 2125 may be connected, through a plurality of conductive bumps 2800, to the plurality of wiring patterns 2005 on the main substrate 2001 of the data storage system 2000 shown in FIG. 13. Each of the plurality of semiconductor chips 2200 may include at least one of the semiconductor devices 10, 100, 100a, 100b, and 100c described above with reference to FIGS. 1 to 10.

While the inventive concept has been particularly shown and described with reference to embodiments thereof, it will be understood that various changes in form and details may be made therein without departing from the spirit and scope of the following claims.

What is claimed is:

1. A semiconductor device comprising a cell structure including a cell region, a connection region, and a peripheral circuit connection region,
wherein the cell structure comprises:
a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes;
a channel structure disposed in the cell region and extending in the vertical direction through the plurality of gate electrodes and the plurality of mold insulating layers, wherein a first end portion of the channel structure protrudes upward from the uppermost mold insulating layer; and
a common source layer arranged in the cell region, connected to the first end portion of the channel structure, and located on the uppermost mold insulating layer, and
wherein the uppermost mold insulating layer comprises a first low-refractive-index layer on a lower surface of the common source layer, a high-refractive-index layer on a lower surface of the first low-refractive-index layer, and a second low-refractive-index layer on a lower surface of the high-refractive-index layer.

2. The semiconductor device of claim 1,
wherein each of a refractive index of the common source layer, a refractive index of the high-refractive-index layer, and a refractive index of the uppermost gate electrode is greater than a refractive index of the first low-refractive-index layer, and
wherein the refractive index of the first low-refractive-index layer is the same as a refractive index of the second low-refractive-index layer.

3. The semiconductor device of claim 1,
wherein a thickness, in the vertical direction, of the high-refractive-index layer is different from a thickness, in the vertical direction, of the second low-refractive-index layer.

4. The semiconductor device of claim 3,
wherein the thickness of the high-refractive-index layer is about 60 nm to about 80 nm, and
wherein the thickness of the second low-refractive-index layer is about 85 nm to about 100 nm.

5. The semiconductor device of claim 1,
wherein the uppermost gate electrode and the second low-refractive-index layer are configured such that an incident light which is incident on the common source layer has a first portion reflected as a first reflected light from a boundary between the uppermost gate electrode and the second low-refractive-index layer,
wherein the second low-refractive-index layer and the high-refractive-index layer are configured such that a second portion of the incident light is reflected as a second reflected light from a boundary between the second low-refractive-index layer and the high-refractive-index layer,
wherein the high-refractive-index layer and the first low-refractive-index layer are configured such that a third portion of the incident light is reflected as a third reflected light from a boundary between the high-refractive-index layer and the first low-refractive-index layer,
wherein the first low-refractive-index layer and the common source layer are configured such that a fourth portion of the incident light is reflected as a fourth reflected light from a boundary between the first low-refractive-index layer and the common source layer,
wherein a phase difference between the first reflected light and the incident light is an odd multiple of half a wavelength of the incident light,
wherein a phase difference between the second reflected light and the incident light is an odd multiple of half the wavelength of the incident light,
wherein a phase difference between the third reflected light and the incident light is an odd multiple of half the wavelength of the incident light, and
wherein a phase difference between the fourth reflected light and the incident light is an odd multiple of half the wavelength of the incident light.

6. The semiconductor device of claim 5,
wherein a phase difference between the first reflected light and the second reflected light is an even multiple of half the wavelength of the incident light, and
wherein a phase difference between the third reflected light and the fourth reflected light is an even multiple of half the wavelength of the incident light.

7. The semiconductor device of claim 1,
wherein a first thickness of the high-refractive-index layer has a value of t₁ satisfying [Equation 1] below:
$${t}_{1} = {A}_{1} * ( \frac{λ}{4 {n}_{1}} ) , \qquad [ Equation 1 ]$$
where A₁ is an odd number,
where λ is a wavelength of an incident light which is incident on the common source layer from a medium of which a refractive index is 1, and
where n₁ is a refractive index of the high-refractive-index layer and is 1 or greater.

8. The semiconductor device of claim 7,
wherein a second thickness of the second low-refractive-index layer has a value of t₂ satisfying [Equation 2] below:
$${t}_{2} = {A}_{2} * ( \frac{λ}{4 {n}_{2}} ) , \qquad [ Equation 2 ]$$
where A₂ is an odd number, and
where n₂ is a refractive index of the second low-refractive-index layer and is 1 or greater.

9. The semiconductor device of claim 1,
wherein a thickness of the uppermost gate electrode is greater than a thickness of each of the remaining gate electrodes among the plurality of gate electrodes.

10. The semiconductor device of claim 1,
wherein each of the first low-refractive-index layer and the second low-refractive-index layer includes silicon oxide, and
wherein the high-refractive-index layer includes silicon nitride.

11. A semiconductor device comprising a cell structure including a cell region, a connection region, and a peripheral circuit connection region,
wherein the cell structure comprises:
a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes;
a channel structure disposed in the cell region and extending in the vertical direction through the plurality of gate electrodes and the plurality of mold insulating layers, wherein a first end portion of the channel structure protrudes upward from the uppermost mold insulating layer; and
a common source layer arranged in the cell region, connected to the first end portion of the channel structure, and located on the uppermost mold insulating layer,
wherein a refractive index of the common source layer is greater than a refractive index of the uppermost mold insulating layer,
wherein the refractive index of the uppermost mold insulating layer is less than a refractive index of the uppermost gate electrode, and
wherein a thickness, in the vertical direction, of the uppermost mold insulating layer is greater than a thickness, in the vertical direction, of each of the remaining mold insulating layers among the plurality of mold insulating layers.

12. The semiconductor device of claim 11,
wherein the uppermost mold insulating layer has a single-layer structure.

13. The semiconductor device of claim 12,
wherein a third thickness of the uppermost mold insulating layer has a value of t₃ satisfying [Equation 3] below:
$${t}_{3} = B * ( \frac{λ}{4 {n}_{3}} ) , \qquad [ Equation 3 ]$$
where B is an even number,
where λ is a wavelength of an incident light which is incident on the common source layer from a medium of which a refractive index is 1, and
where n₃ is a refractive index of the uppermost mold insulating layer and is 1 or greater.

14. The semiconductor device of claim 11,
wherein the uppermost gate electrode and the uppermost mold insulating layer are configured such that an incident light which is incident on the common source layer has a fifth portion reflected as a fifth reflected light from a boundary between the uppermost gate electrode and the uppermost mold insulating layer, and
wherein a phase difference between the fifth reflected light and the incident light is an odd multiple of half a wavelength of the incident light.

15. The semiconductor device of claim 14,
wherein the uppermost mold insulating layer and the common source layer are configured such that a sixth portion of the incident light is reflected as a sixth reflected light from a boundary between the uppermost mold insulating layer and the common source layer, and
wherein a phase difference between the sixth reflected light and the fifth reflected light is an even multiple of half the wavelength of the incident light.

16. The semiconductor device of claim 11,
wherein a sum of a thickness, in the vertical direction, of the common source layer and the thickness, in the vertical direction, of the uppermost mold insulating layer is about 100 nm to about 300 nm.

17. The semiconductor device of claim 11,
wherein a thickness, in the vertical direction, of the uppermost gate electrode is greater than a thickness, in the vertical direction, of each of the remaining gate electrodes among the plurality of gate electrodes.

18. A semiconductor device comprising:
a peripheral circuit structure comprising a peripheral circuit transistor and a peripheral circuit wiring structure; and
a cell structure stacked on the peripheral circuit structure and comprising a cell region, a connection region, and a peripheral circuit connection region,
wherein the cell structure comprises:
a plurality of gate electrodes and a plurality of mold insulating layers disposed on an upper surface of a substrate and alternately stacked one by one in a vertical direction in the cell region, wherein the vertical direction is perpendicular to the upper surface of the substrate, and wherein an uppermost mold insulating layer that is the highest, in the vertical direction relative to the upper surface of the substrate, among the plurality of mold insulating layers is on an upper surface of an uppermost gate electrode that is the highest, in the vertical direction relative to the upper surface of the substrate, among the plurality of gate electrodes;
a channel structure disposed in the cell region and extending in the vertical direction through the plurality of gate electrodes and the plurality of mold insulating layers, wherein a first end portion of the channel structure protrudes upward from the uppermost mold insulating layer;
a common source layer arranged in the cell region, connected to the first end portion of the channel structure, and located on the uppermost mold insulating layer;
a plurality of pad portions respectively extending from the plurality of gate electrodes in the vertical direction and disposed in the connection region; and
a stack insulating layer disposed in the connection region and the peripheral circuit connection region and surrounding the plurality of gate electrodes and the plurality of mold insulating layers, and
wherein a thickness, in the vertical direction, of the uppermost mold insulating layer is greater than a thickness, in the vertical direction, of each of the remaining mold insulating layers among the plurality of mold insulating layers.

19. The semiconductor device of claim 18,
wherein the uppermost mold insulating layer comprises:
a first low-refractive-index layer;
a high-refractive-index layer on a lower surface of the first low-refractive-index layer and having a higher refractive index than the first low-refractive-index layer; and
a second low-refractive-index layer on a lower surface of the high-refractive-index layer and having a lower refractive index than the high-refractive-index layer,
wherein the uppermost gate electrode and the second low-refractive-index layer are configured such that an incident light which is incident on the common source layer has a first portion reflected as a first reflected light from a boundary between the uppermost gate electrode and the second low-refractive-index layer,
wherein the second low-refractive-index layer and the high-refractive-index layer are configured such that a second portion of the incident light is reflected as a second reflected light from a boundary between the second low-refractive-index layer and the high-refractive-index layer,
wherein the high-refractive-index layer and the first low-refractive-index layer are configured such that a third portion of the incident light is reflected as a third reflected light from a boundary between the high-refractive-index layer and the first low-refractive-index layer,
wherein the first low-refractive-index layer and the common source layer are configured such that a fourth portion of the incident light is reflected as a fourth reflected light from a boundary between the first low-refractive-index layer and the common source layer,
wherein a phase difference between the first reflected light and the incident light is an odd multiple of half a wavelength of the incident light,
wherein a phase difference between the second reflected light and the incident light is an odd multiple of half the wavelength of the incident light,
wherein a phase difference between the third reflected light and the incident light is an odd multiple of half the wavelength of the incident light, and
wherein a phase difference between the fourth reflected light and the incident light is an odd multiple of half the wavelength of the incident light.

20. The semiconductor device of claim 18,
wherein the uppermost gate electrode and the uppermost mold insulating layer are configured such that an incident light has a fifth portion reflected as a fifth reflected light from a boundary between the uppermost gate electrode and the uppermost mold insulating layer,
wherein the uppermost mold insulating layer and the common source layer are configured such that a sixth portion of the incident light is reflected as a sixth reflected light from a boundary between the uppermost mold insulating layer and the common source layer,
wherein a phase difference between the fifth reflected light and the incident light is an odd multiple of half a wavelength of the incident light, and
wherein a phase difference between the sixth reflected light and the incident light is an odd multiple of half the wavelength of the incident light.
